(19) United States
(12) Patent Application Publication
(10) Pub. No.: US 2025/0221156 A1
(43) Pub. Date: Jul. 3, 2025

(54) PHOTOELECTRIC DEVICE, AND PREPARATION METHOD THEREOF

(71) Applicants: Guangdong Juhua Research Institute of Advanced Display, Guangzhou (CN); TCL Technology Group Corporation, Huizhou (CN)

(72) Inventor: Fuqiang QIANG, Guangzhou (CN)

(73) Assignees: Guangdong Juhua Research Institute of Advanced Display, Guangzhou (CN); TCL Technology Group Corporation, Huizhou (CN)

(21) Appl. No.: 18/991,124

(22) Filed: Dec. 20, 2024

(30) Foreign Application Priority Data
Dec. 30, 2023 (CN) 202311874286.1

(51) Int. Cl. H10K 50/165; B82Y 20/00; H10K 50/115; H10K 50/155; H10K 50/17; H10K 71/15; H10K 71/40; H10K 71/60; H10K 85/50; H10K 102/00

(52) U.S. Cl. CPC H10K 50/165; B82Y 20/00; H10K 50/115; H10K 50/155; H10K 50/171; H10K 71/15; H10K 71/40; H10K 71/60; H10K 85/50; H10K 2102/351

(57) ABSTRACT

Disclosed are a photoelectric device, and a preparation method thereof. The photoelectric device includes an anode, a photoelectric functional layer, a first electron functional layer, a second electron functional layer, and a cathode disposed sequentially in stack. A material of the first electron functional layer includes a first inorganic nanoparticle and a first ligand, a material of the second electron functional layer includes a second inorganic nanoparticle, and the photoelectric device has a high luminous efficiency.

This application claims priority to Chinese Application No. 202311874286.1, entitled “PHOTOELECTRIC DEVICE, PREPARATION METHOD THEREOF, AND DISPLAY APPARATUS”, filed on Dec. 30, 2023. The entire disclosures of the above application are incorporated herein by reference.

### TECHNICAL FIELD

The present disclosure relates to a field of display technologies, and in particular to a photoelectric device, and a preparation method thereof.

### BACKGROUND

At present, the widely used photoelectric devices are an organic light-emitting diode (OLED) and a quantum dot light-emitting diode (QLED). The OLED has become a mainstream technology in the field of display technologies because of excellent display performances such as self-luminous, simple structure, ultra-thin, fast response speed, wide viewing angle, low power consumption, and flexible display. The QLED has become a strong competitor of the OLED in recent years due to advantages of colour saturation of emitted lights and adjustable wavelength, as well as a high photoluminescence quantum yield and a high electroluminescence quantum yield.

A conventional structure of the OLED or the QLED generally includes an anode, a hole injection layer, a hole transport layer, a light emitting layer, an electron transport layer, an electron injection layer, and a cathode. Under an action of an electric field, holes generated by the anode and electrons generated by the cathode move, inject into the hole transport layer and the electron transport layer respectively, and finally migrate to the light-emitting layer. When the holes and electrons meet in the light-emitting layer, energy excitons are generated, thereby exciting light-emitting molecules and ultimately generating visible light.

Therefore, a luminous efficiency of a photoelectric device is low and needs to be further improved.

### Technical Solution

In view of this, the present disclosure provides a photoelectric device, and a preparation method thereof.

According to a first aspect, the present disclosure provides a photoelectric device including an anode, a photoelectric functional layer, a first electron functional layer, a second electron functional layer, and a cathode disposed sequentially in stack. A material of the first electron functional layer includes a first inorganic nanoparticle and a first ligand, and a material of the second electron functional layer includes a second inorganic nanoparticle.

According to a second aspect, the present disclosure further provides a method for preparing a photoelectric device including:
providing a preform comprising an anode and a photoelectric functional layer disposed sequentially in stack;
disposing a first inorganic nanoparticle and a first ligand on the photoelectric functional layer to form a first electron functional layer;
disposing a second inorganic nanoparticle on the first electron functional layer to form a second electron functional layer; and
forming a cathode on the second electron functional layer to obtain the photoelectric device.

According to a third aspect, the present disclosure further provides another method for preparing a photoelectric device including:
providing a preform comprising a cathode;
disposing a second inorganic nanoparticle on the cathode to form a second electron functional layer;
disposing a first inorganic nanoparticle and a first ligand on the second electron functional layer to form a first electron functional layer; and
forming a photoelectric functional layer and an anode sequentially on the first electron functional layer to obtain the photoelectric device.

The photoelectric device provided by the present disclosure has a high luminous efficiency.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a schematic diagram of a photoelectric device provided by an embodiment of the present disclosure.

FIG. 2 is a flowchart of a method for preparing a photoelectric device according to an embodiment of the present disclosure

FIG. 3 is a flowchart of a method for preparing a photoelectric device according to another embodiment of the present disclosure.

### DETAILED DESCRIPTION

Technical solutions in embodiments of the present disclosure will be clearly and completely described below in conjunction with drawings in the embodiments of the present disclosure. Obviously, the embodiments are only a part of embodiments of the present disclosure, rather than all the embodiments. Based on the embodiments in the present disclosure, all other embodiments obtained by those skilled in the art without creative work fall within the protection scope of the present disclosure.

In the present disclosure, unless otherwise specified, directional terms such as “upper” or “lower” generally refers to an upper direction or a lower direction in the actual use or working state of a device, specifically a drawing direction in the drawings. “inside” and “outside” are for an outline of the device. In addition, in a description of the present application, a term “including” means “including but not limited to”. Terms as first, second, third and so on are used for indication only, and do not impose numerical requirements or establish order.

In the present disclosure, “and/or” is used to describe an association of associated objects, and means that there may be three relationships, for example, “A and/or B” may refer to three cases: a first case refers to the presence of A alone; a second case refers to the presence of both A and B; a third case refers to the presence of B alone, where A and B may be singular or plural.

In the present disclosure, “at least one” refers to one or more, and “more” in the “one or more” refers to two or more. “one or more”, “at least one of the followings”, or similar expressions thereof refer to any combination of items listed, including any combination of a singular item or multiple items. For example, “at least one of a, b, or c”, or “at least one of a, b, and c”, may each represent: a, b, c, a-b (i.e., a and b), a-c, b-c, or a-b-c, wherein a, b, and c may be single or plural.

Various embodiments of the present disclosure may be presented in a form of range. It should be understood that a description in the form of range is merely for convenience and brevity, and should not be construed as a hard limitation on the scope of the disclosure. Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

At present, inorganic nanoparticles such as an nano zinc oxide are generally used as a material of an electron functional layer, the nano zinc oxide is conducive to an injection of electrons from a cathode to a light emitting layer, and as the nano zinc oxide has a lower valence band energy level, it can effectively block holes. However, a conduction band level of the nano zinc oxide is still lower than that of a blue quantum dot, and the nano zinc oxide has surface defects which adsorb oxygen. During the operating of the photoelectric device, a difference of conduction band energy level between the nanoparticle zinc oxide and the light-emitting layer makes electron injection relatively difficult, resulting in high brightening voltage and high operating voltage. And the defects on the surface of the nano zinc oxide may lead to serious interfacial charge recombination, resulting in efficiency loss of the photoelectric device.

Technical solutions of the present disclosure are as follows:

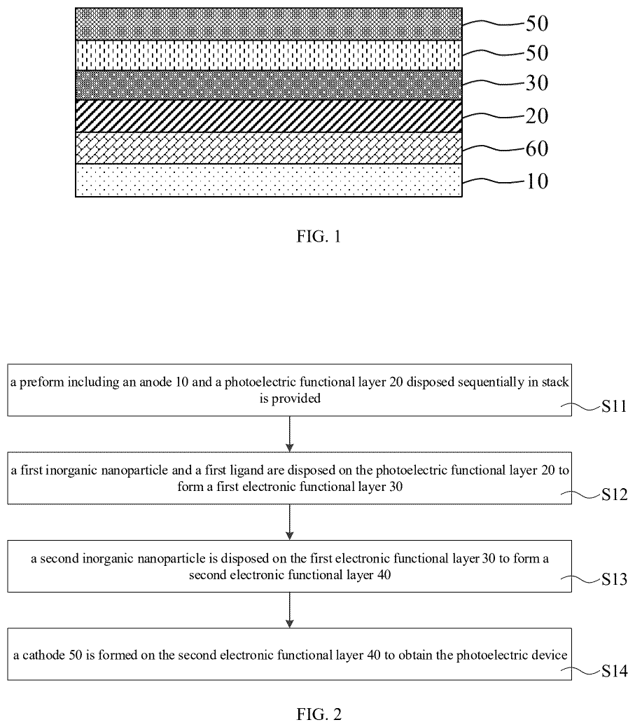

In the first aspect, referring to FIG. 1, an embodiment of the present disclosure provides a photoelectric device, including an anode 10, a photoelectric functional layer 20, a first electron functional layer 30, a second electron functional layer 40, and a cathode 50 disposed sequentially in stack. A material of the first electron functional layer 30 includes a first inorganic nanoparticle and a first ligand, and a material of the second electron functional layer 40 includes a second inorganic nanoparticle.

It should be noted that the first ligand is attached to the surface of the first inorganic nanoparticle.

In the photoelectric device provided by the present disclosure, the first ligand in the first electron functional layer 30 close to a photoelectric functional layer 20 can improve a conduction band energy level of the first inorganic nanoparticle, reduce an injection barrier of electrons injected from the first electron functional layer 30 into the photoelectric functional layer 20, promote a recombination of electrons and holes, and improve photoelectric efficiency. The first ligand in the first electron functional layer 30 can passivate surface defects of the first inorganic nanoparticle, and reduce an exciton quenching of the photoelectric functional layer 20 by a defect energy level of the first inorganic nanoparticle. In addition, the second inorganic nanoparticle in the second electron-functional layer 40 close to the cathode 50 can maintain a high electron mobility, which facilitates an injection of electrons from the cathode 50 to the second electron-functional layer 40.

In the present disclosure, a conduction band energy level of an electron functional layer is stepped, which can alleviate a problem of difficulty in electron injection of the photoelectric device, promote the injection and transportation of electrons, and improve the electron mobility, thereby reducing a turn-on voltage of the photoelectric device and improving a photoelectric efficiency of the photoelectric device.

In some embodiments, a number of carbon atoms in a main chain of the first ligand ranges from 2 to 10.

Preferably, in some embodiments, the number of carbon atoms in the main chain of the first ligand ranges from 2 to 6. Within a range of the number of carbon atoms in the main chain above, the first ligand is a short chain ligand with appropriate steric hindrance, which can promote a compact arrangement of the first inorganic nanoparticle and improve the densification of the first electron functional layer.

In some embodiments, the number of carbon atoms in the main chain of the first ligand ranges from 3 to 8.

In some embodiments, the number of carbon atoms in the main chain of the first ligand ranges from 4 to 5.

In some embodiments, the first ligand includes a coordination group. The coordination group passivate the surface defects of the first inorganic nanoparticle, and reduce the exciton quenching of the photoelectric functional layer 20 by the defect energy level of the first inorganic nanoparticle.

Furthermore, the coordination group includes one or more of an amine group, a carboxyl group, a thiol group, a hydroxyl group, a cyano group, a carbonyl group, an ester group, an amide group, and an ether group. The coordination group can coordinate with the first inorganic nanoparticle to cause dipolar polarization on the surface of the first inorganic nanoparticle, thereby increasing the conduction band level.

In some embodiments, the first ligand includes one or more of ethanolamine, ethylenediamine, diethylenetriamine, triethylenetetramine, ethylene diamine tetraacetic acid, 3-mercaptopropionic acid, thiophenol, 2-(methylamino) ethanol, oxalic acid, malic acid, caffeic acid, benzyl mercaptan, 2-(BOC-amino) ethanethiol, allyldiglycol, ethyl cyanoacetate, and 4-cyanobenzoic acid.

In some embodiments, in the first electron functional layer 30, a molar ratio of the first inorganic nanoparticle to the first ligand is 1:(100˜300), for example, 1:120, 1:150, 1:180, 1:200, 1:220, 1:250, 1:280, or the like. Within a range of the molar ratio above, it is beneficial for the first ligand to adjust the conduction band energy level of the first inorganic nanoparticle and promote the injection of electrons.

In some embodiments, a material of the first inorganic nanoparticle and a material of the second inorganic nanoparticle each independently include a first doped-type metal oxide particle, a first undoped-type metal oxide particle, a group IIB-VIA semiconductor material, a group IIIA-VA semiconductor material, and a group IB-IIIA-VIA semiconductor material. The first undoped-type metal oxide particle includes one or more of ZnO, TiO₂, SnO₂, ZrO₂, and Ta₂O₅. The first doped-type metal oxide particle includes one or more of ZnO, TiO₂, SnO₂, ZrO₂. Ta₂O₅ and Al₂O₃, and a doping element of the first doped-type metal oxide particle includes one or more of Al, Mg, Li, Mn, Y, La, Cu, Ni, Zr, Ce, In, and Ga. The group IIB-VIA semiconductor material includes one or more of ZnS, ZnSe, and CdS. The group IIIA-VA semiconductor material includes one or more of InP and GaP. The group IB-IIIA-VIA semiconductor material includes one or more of CuInS and CuGaS.

It should be noted that the material of the first inorganic nanoparticle and the material of the second inorganic nanoparticle are the same or different.

Preferably, the material of the first inorganic nanoparticle and the material of the second inorganic nanoparticle are the same.

In some embodiments, an average particle size of the first inorganic nanoparticle ranges from 3 nm to 20 nm, such as 5 nm, 8 nm, 10 nm, 12 nm, 15 nm, 18 nm, and the like.

In some embodiments, an average particle size of the second inorganic nanoparticle ranges from 3 nm to 20 nm, such as 5 nm, 8 nm, 10 nm, 12 nm, 15 nm, 18 nm, and the like.

In some embodiments, a thickness of the first electron functional layer 30 ranges from 10 nm to 30 nm, such as 12 nm, 15 nm, 18 nm, 20 nm, 22 nm, 25 nm, 28 nm, and the like.

In some embodiments, a thickness of the second electron functional layer 40 ranges from 10 nm to 30 nm, such as 12 nm, 15 nm, 18 nm, 20 nm, 22 nm, 25 nm, 28 nm, and the like.

In some embodiments, the material of the second electron functional layer 40 further includes a second ligand, and the second ligand includes one or more of an acetate ligand, a nitrate ligand, an oxalate ligand, a chloride ligand, a bromide ligand, a diethyl ligand. It should be noted that the second ligand is mainly generated by an anion in a precursor introduced during a synthesis of the second inorganic nanoparticle.

It should be noted that the first electron functional layer 30 also includes a third ligand, and the third ligand includes one or more of an acetate ligand, a nitrate ligand, an oxalate ligand, a chloride ligand, a bromide ligand, a diethyl ligand. Since it is difficult for the first ligand to completely replace the third ligand, a small amount of the third ligand is present.

It can be understood that a content of the third ligand in the first electron functional layer 30 is less than a content of the second ligand in the second electron functional layer 40.

In some embodiments, the photoelectric device includes a light emitting diode.

In some embodiments, the photoelectric device further includes a hole functional layer 60 disposed between the anode 10 and the photoelectric functional layer 20.

The hole functional layer 60 includes one or more of a hole injection layer and a hole transport layer.

The first electron functional layer 30 or the second electron functional layer 40 includes one or more of an electron injection layer and an electron transport layer.

In some embodiments, the anode 10 and the cathode 50 each independently include one or more of a metal, a carbon material, and a metal oxide. The metal includes one or more of Al, Ag, Cu, Mo, Au, Ba, Ca, Yb and Mg. The carbon material includes one or more of graphite, carbon nanotube, graphene, and carbon fiber. The metal oxide includes one or more of ITO, FTO, ATO, AZO, GZO, IZO, MZO, MoO₃, and AMO. the anode 10 and the cathode 50 each can be a composite electrode, and the composite electrode includes one or more of AZO/Ag/AZO, AZO/AI/AZO, ITO/Ag/ITO, ITO/AI/ITO, ZnO/Ag/ZnO, ZnO/Al/ZnO, ZnS/Ag/ZnS, ZnS/Al/ZnS, TiO₂/Ag/TiO₂, and TiO₂/Al/TiO₂. “/” represents a laminated structure, and for example, AZO/Ag/AZO represents a composite electrode including an AZO layer, an Ag layer, and an AZO layer disposed sequentially in stack.

The photoelectric functional layer includes a light-emitting material, and the light-emitting material includes an organic light-emitting material or a quantum dot light-emitting material.

The organic light-emitting material may be selected from but not limited to one or more of 4,4′-bis(N-carbazole)-1,1′-biphenyl:tris[2-(p-tolyl)pyridinyl iridium (III)](CBP:Ir(mppy)₃), 4,4′,4″-tris(carbazol-9-yl)triphenylamine:tris[2-(p-tolyl)pyridinyl iridium](TCTX:Ir(mmpy)), diarylanthracene derivatives, stilbene aromatic derivatives, pyrene derivatives, fluorene derivatives, a TBPe fluorescent material, a TTPX fluorescent material, a TBRb fluorescent material, a DBP fluorescent material, a DBP fluorescent material, a DBP fluorescent material, a TTA material, a TADF material, a polymer including a B—N covalent, a HLCT material, and an Exciplex luminescent material.

The quantum dot light-emitting material may be selected from but not limited to one or more of a quantum dot with a single component, a quantum dot with a core-shell structure, and a perovskite-type semiconductor material.

A material of the quantum dot with the single component, a core material of the quantum dot with the core-shell structure, and a shell material of the quantum dot with the core-shell structure each may be independently selected from but not limited to one or more of a group II-VI compound, a group IV-VI compound, a group III-V compound, a group I-III-VI compound. The quantum dot with a core-shell structure includes one or more shell layers. The group II-VI compound may be selected from but not limited to one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The group IV-VI compound may be selected from but not limited to one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The group III-V compound may be selected from but not limited to one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The group I-III-VI compound may be selected from but not limited to one or more of CuInS₂, CuInSe₂, and AgInS₂.

As an example, the quantum dot with the core-shell structure may be selected from but not limited to one or more of CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS. “/” in the above description such as CdSe/ZnS means that a substance after “/” (as the shell layer) wraps a substance before “/” (as the core).

The perovskite-type semiconductor material may be selected from but not limited to a doped inorganic perovskite type semiconductor, a non-doped inorganic perovskite type semiconductor, or an organic-inorganic hybrid perovskite type semiconductor. The inorganic perovskite type semiconductor has a general structural formula of AMX₃, A is Cs⁺, and M is a divalent metal cation which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion which is selected from one or more of Cl, Br, and I. The organic-inorganic hybrid perovskite type semiconductor has a general structural formula of BMX₃, B is a formamidyl, and M is a divalent metal cation which is selected from one or more of Ph²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion which is selected from one or more of Cl, Br, and I.

In some embodiments, a material of the hole functional layer includes one or more of 4,4′-N,N′-dicarbazolyl-biphenyl, N,N′-diphenyl-N, N′-bis(1-naphthyl)-1,1′-biphenyl-4,4′-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro, N,N′-bis(4-(N,N′-diphenyl-amino)phenyl)-N, N′-diphenylbenzidine, 4,4′,4′-tris(N-carbazolyl)-triphenylamine, 4,4′,4″-tris(carbazol-9-yl)-triphenylamine, trichloroisocyanuric acid, a terbium-doped phosphate-based green luminescent material, hexaazatriphenylenchexacabonitrile, 4,4′,4″-tris(N-3-methylphenyl-N-phenylamino)triphenylamine, poly(9,9-dioctylfluorene-co-N-(4-butylphenyl)diphenylamine), poly[(9,9′-dioctylfluorene-2,7-diyl)-co-(4,4′-(N-(4-sec-butylphenyl)diphenylamine)], poly(4-butylphenyl-diphenylamine)], poly[bis(4-phenyl) (4-butylphenyl)amine], polyaniline, polypyrrole, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylene vinylidene], copper (II) phthalocyanine, aromatic tertiary amine, polynuclear aromatic tertiary amine, 4,4′-bis(p-carbazolyl)-1,1′-biphenyl, N,N,N′,N′-tetraphenylbenzidine, PEDOT, PEDOT:PSS and derivatives thereof, PEDOT:PSS doped with s-MoO₃, poly(N-vinylcarbazole) and derivatives thereof, polymethacrylate and derivatives thereof, poly(9,9-octylfluorene) and derivatives thereof, poly(spirofluorene) and derivatives thereof, N,N′-bis(naphthalen-1-yl)-N,N′-diphenylbenzidine, spiro-NPB, nano-polycrystalline diamond, microcrystalline cellulose, tetracyanoquinone dimethane, doped graphene, undoped graphene, a second doped-type metal oxide particle, a second undoped-type metal oxide particle, a metal sulfide, a metal selenide and a metal nitride. A metal oxide of the second doped-type metal oxide particle and the second undoped-type metal oxide particle each independently include one or more of MoO₃, WO₃, NiO, CrO₃, CuO, and V₂O₅. A doping element in the second doped-type metal oxide particle includes Mo, W, Ni, Cr, Cu, and V. The metal sulfide includes one or more of CuS, MoS₃, and WS₃. The metal selenide includes one or more of MoSe₃ and WSe₃. The metal nitride includes p-type gallium nitride.

In the second aspect, referring to FIG. 2, an embodiment of the present disclosure provides a method for preparing a photoelectric device including steps S11˜S14.

In step S11, a preform including an anode 10 and a photoelectric functional layer 20 disposed sequentially in stack is provided.

In step S12, a first inorganic nanoparticle and a first ligand are disposed on the photoelectric functional layer 20 to form a first electron functional layer 30.

In step S13, a second inorganic nanoparticle is disposed on the first electron functional layer 30 to form a second electron functional layer 40.

In step S14, a cathode 50 is formed on the second electron functional layer 40 to obtain the photoelectric device.

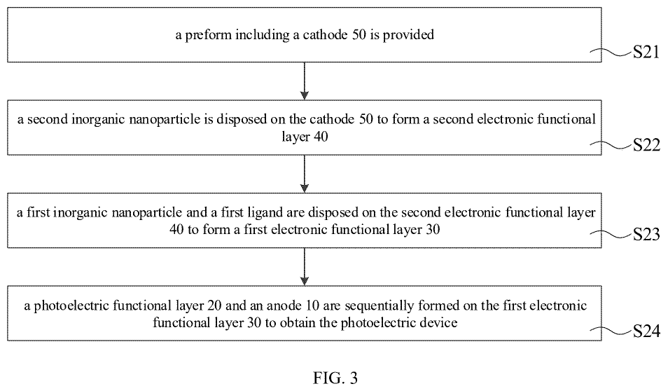

It can be understood that the photoelectric device prepared by the above method is a photoelectric device with an upright structure. Referring to FIG. 3, another embodiment of the present disclosure provides another method for preparing a photoelectric device including steps S21˜S24.

In step S21, a preform including a cathode 50 is provided.

In step S22, a second inorganic nanoparticle is disposed on the cathode 50 to form a second electron functional layer 40.

In step S23, a first inorganic nanoparticle and a first ligand are disposed on the second electron functional layer 40 to form a first electron functional layer 30.

In step S24, a photoelectric functional layer 20 and an anode 10 are sequentially formed on the first electron functional layer 30 to obtain the photoelectric device.

In some embodiments, in step S11, the preform further includes a hole functional layer 60 disposed between the anode 10 and the photoelectric functional layer 20 in step S11.

In some embodiments, in step S12, a step of forming the first electron functional layer 30 includes disposing the mixed solution comprising the first inorganic nanoparticle and the first ligand on the photoelectric functional layer 20 to form the first electron functional layer 30.

In some embodiments, in the mixed solution, a molar ratio of the first inorganic nanoparticle to the first ligand is 1:(100˜300), such as 1:120, 1:150, 1:180, 1:200, 1:220, 1:250, 1:280, and the like. Within a range of the molar ratio above, it is beneficial for the first ligand to adjust the conduction band energy level of the first inorganic nanoparticle and promote the injection of electrons.

In some embodiments, the mixed solution including the first ligand and a first inorganic nanoparticle dispersion with the first inorganic nanoparticle. The first inorganic nanoparticle dispersion and the first ligand are mixed to obtain the mixed solution.

In some embodiments, in the first inorganic nanoparticle dispersion, a mass concentration of the first inorganic nanoparticle ranges from 15 mg/mL to 30 mg/mL, such as 18 mg/mL, 20 mg/mL, 22 mg/mL, 25 mg/mL, 28 mg/mL, and the like. Within a range of the mass concentration above, it is conducive to dissolution and dispersion of the first inorganic nanoparticle.

In some embodiments, the mixing time of the first inorganic nanoparticle dispersion and the first ligand ranges from 10 minutes to 60 minutes, such as 15 minutes, 20 minutes, 25 minutes, 30 minutes, 35 minutes, 40 minutes, 45 minutes, 55 minutes, and the like. A temperature of the mixing ranges from 15° C. to 60° C., such as 20° C., 25° C., 30° C., 35° C., 40° C., 45° C., 55° C., 55° C., and the like.

Thus, conditions of the mixing above are conducive to a full contact between the first inorganic nanoparticle and the first ligand.

In some embodiments, after disposing the mixed solution on the photoelectric functional layer 20, a first thermal annealing is performed.

Furthermore, a temperature of the first thermal annealing ranges from 80° C. to 100° C., such as 82° C., 85° C., 88° C., 90° C., 92° C., 95° C., 98° C., and the like. The time of the first thermal annealing ranges from 20 minutes to 30 minutes, such as 22 minutes, 24 minutes, 26 minutes, 28 minutes, and the like.

Thus, under conditions of the first thermal annealing above, it is conducive to removing a solvent from the mixed solution sufficiently.

In some embodiments, in step S13, a step of forming the second electron functional layer 40 includes disposing a second inorganic nanoparticle dispersion on the first electron functional layer 30 to form the second electron functional layer 40.

In some embodiments, a mass concentration of the second inorganic nanoparticle ranges from 15 mg/mL to 30 mg/mL, such as 18 mg/mL, 20 mg/mL, 22 mg/mL, 25 mg/mL, 28 mg/mL, and the like.

In some embodiments, after disposing the second inorganic nanoparticle dispersion on the first electron functional layer 30, a second thermal annealing is performed.

Furthermore, a temperature of the second thermal annealing ranges from 80° C. to 100° C., such as 82° C., 85° C., 88° C., 90° C., 92° C., 95° C., 98° C., and the like. The time of the second thermal annealing ranges from 20 minutes to 30 minutes, such as 22 minutes, 24 minutes, 26 minutes, 28 minutes, and the like.

Thus, under conditions of the second thermal annealing above, it is conducive to removing a solvent from the second inorganic nanoparticle dispersion sufficiently.

In some embodiments, the first inorganic nanoparticle dispersion further includes a first solvent. The second inorganic nanoparticle dispersion further includes a second solvent.

In some embodiments, the first solvent and the second solvent each independently include one or more of chlorobenzene, diethylene glycol monobutyl ether, 3-methoxy-1-butanol, triethylene glycol monobutyl ether, diglyme, methanol, ethanol, 1-propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid, and cresol.

In the third aspect, an embodiment of the present disclosure provides a display apparatus including the photoelectric device as described above. The display apparatus may be any electronic product with a display function, including but not limited to a smartphone, a tablet computer, a notebook computer, a digital camera, a digital video camera, a smart wearable device, a smart weighing electronic scale, a vehicle display, a television or an electronic book. The smart wearable device may be, for example, a smart bracelet, a smart watch, a virtual reality (VR) helmet, or the like.

In the following, the present disclosure is specifically described by specific embodiments, and the following examples are only partial examples of the present disclosure and are not limited to the present disclosure.

### Example 1

This embodiment provides a photoelectric device and preparation method thereof, and the preparation method includes steps S1˜S7.

In step S1, an ITO glass substrate was cleaned with detergent to initially remove stains on the surface, then ultrasonically cleaned in deionized water, acetone, absolute ethanol and deionized water for 20 minutes respectively to remove impurities on the surface, and finally, it was blown dry with high-purity nitrogen to obtain an ITO anode.

In step S2, the ITO anode was disposed on a spin coater, then the ITO anode was spin-coated with a TFB solution at a rotating speed of 3000 rpm for 30 seconds to form a film, CAS number of the TFB is 220797-16-0, and spin coating was followed by a thermal annealing treatment at 150° C. for 30 minutes to form a hole transport layer with a thickness of 30 nm.

In step S3, a substrate spin-coated with the hole transport layer was disposed on a spin coater, then the substrate was spin-coated with a solution of CdSe quantum dots at a rotating speed of 3000 rpm for 30 seconds to form a film, and spin coating was followed by a thermal annealing treatment at 80° C. for 30 minutes to form a light-emitting layer with a thickness of 30 nm.

In step S4, zinc acetate dehydrate was added into N,N-dimethylformamide to form a solution with a total concentration of 0.5 mol/L, 0.5 mol of KOH ethanol solution was dropwise added at room temperature, and was continuously stirred for 1 hour to obtain a clear solution. Ethyl acetate was configured as a precipitating agent to precipitate ZnO nanoparticles, the ZnO nanoparticles were collected after centrifugation, and then the ZnO nanoparticles were dissolved and dispersed with appropriate amount of ethanol to obtain a dispersion of the ZnO nanoparticles and ethanol. 15 mmol/mL of diethylenetriamine was added into the dispersion, and a molar ratio of ZnO to diethylenetriamine is 1:200. After stirring at 25° C. for 30 minutes, a mixed liquid was obtained by filtering through a filter head of 0.2 μm. The mixed liquid was spin-coated on the light-emitting layer at a rotating speed of 3000 rpm for 30 seconds, and a first electron functional layer with a thickness of 20 nm was formed by a thermal annealing at 100° C. for 20 minutes.

In step S5, the substrate spin-coated with the first electron functional layer was disposed on a spin coater, then the substrate was spin-coated with the dispersion of the ZnO nanoparticles and ethanol at a rotating speed of 3000 rpm for 30 seconds, and a second electron functional layer with a thickness of 20 nm was formed by a thermal annealing at 80° C. for 30 minutes.

In step S6, the substrate on which each functional layer had been disposed was placed in an evaporation chamber, and a layer of metal silver with a thickness of 100 nm configured as a cathode was formed by thermal evaporation through a mask plate.

In step S7, after the cathode was formed, the substrate was encapsulated to obtain the photoelectric device.

### Examples 2˜3

Examples 2˜3 are each essentially the same as the Example 1, except that, in Example 2, the diethylenetriamine is replaced by ethylenediaminetetraacetic acid, and in Example 3, the diethylenetriamine is replaced by ethanolamine.

### Examples 4˜5

Examples 4˜5 are each essentially the same as the Example 1, except that, in Example 4, ZnO in the first electron functional layer and the second electron functional layer are replaced by TiO₂ respectively, and in Example 5, only the ZnO in the first electron functional layer is replaced by TiO₂.

### Examples 6˜7

Examples 6˜7 are each essentially the same as the Example 1, except that, in Example 6, a concentration of the diethylenetriamine is 15 mmol/mL and the molar ratio of ZnO to diethylenetriamine is 1:300, while in Example 7, a concentration of the diethylenetriamine is 5 mmol/mL and the molar ratio of ZnO to diethylenetriamine is 1:100.

### Examples 8˜9

Examples 8˜9 are each essentially the same as the Example 1, except that, a mixing time of the ZnO and the diethylenetriamine in Example 8 is 60 minutes, and a mixing time of the ZnO and the diethylenetriamine in Example 9 is 10 minutes.

### Examples 10˜11

Examples 10˜11 are each essentially the same as the Example 1, except that, a mixing temperature of the ZnO and the diethylenetriamine in Example 10 is 60° C., and a mixing temperature of the ZnO and the diethylenetriamine in Example 11 is 15° C.

### Examples 12˜13

Examples 12˜13 are each essentially the same as the Example 1, except that, the thickness of the first electron functional layer is 30 nm in Example 12, and the thickness of the first electron functional layer is 10 nm in Example 13.

### Comparative Examples 1˜3

Comparative Examples 1˜3 are each essentially the same as the Example 1, except that, Comparative Example 1 do not include the first electron functional layer, Comparative Example 2 do not include the second electron functional layer, and in Comparative Example 3, the second electron functional layer is close to the light-emitting layer and the first electron functional layer is close to the cathode.

The luminous efficiency (C.E@max) and the turn-on voltage of each of Examples 1˜13 and Comparative Examples 1˜3 were tested respectively, and the results are shown in Table 1.

The luminous efficiency (C.E@max) was tested and calculated by a Keithley 2400 high-precision digital source meter, an Ocean Optic USB2000+spectrometer and a LS-160 luminance meter. A test method of the turn-on voltage was as follows: when the luminance reached Init, a voltage value was obtained in an efficiency test system built by Keithley 6485, and the voltage value was the turn-on voltage.

TABLE 1

| | C.E@ₘₐₓ | turn-on voltage |
|---|---|---|
| | (cd/A) | (V) |
| Example 1 | 15 | 3 |
| Example 2 | 13 | 4 |
| Example 3 | 11 | 4 |
| Example 4 | 9 | 5 |
| Example 5 | 8 | 4.5 |
| Example 6 | 13 | 3.5 |
| Example7 | 11 | 3.2 |
| Example 8 | 14 | 3.5 |
| Example 9 | 13 | 3.2 |
| Example 10 | 11 | 4.5 |
| Example 11 | 10 | 4 |
| Example 12 | 15 | 4 |
| Example 13 | 12 | 3 |
| Comparative Example 1 | 5 | 5.5 |
| Comparative Example 2 | 5 | 5 |
| Comparative Example 3 | 4 | 5.8 |

According to Examples 1˜5 and Comparative Examples 1˜3, compared with Comparative Examples 1˜3, the luminous efficiency of the photoelectric device provided by the present disclosure is significantly improved, and the turn-on voltage is decreased. An electron transport layer with double-layers prepared by a conventional inorganic nanoparticle and an inorganic nanoparticle including the first ligand forms a conduction band energy pole gradient so as to beneficial to electrons injection and transport. Comparative Example 2 uses the inorganic nanoparticle including the first ligand to prepare the electron transport layer, and the performance of the photoelectric device thereof is slightly better than that of Comparative Example 1, but is still worse than that of Example 1, which may be because it reduces an injection barrier between the electron transport layer and the light emitting layer, but correspondingly increases an injection barrier between the cathode and the electron transport layer. In addition, the first ligand with different chain lengths can also affect the performance of the photoelectric device. Among them, the first ligand of Example 1 has a moderate chain length, and the performance of the photoelectric device is relatively better.

According to Examples 1, 6, 7 and Comparative Example 1, a content of the first ligand has a certain influence on the luminous efficiency and the turn-on voltage of the photoelectric device within the range provided in the present disclosure, and when the content of the first ligand is moderate, the luminous efficiency of the photoelectric device is higher and the turn-on voltage is lower.

According to Examples 1, 8, 11 and Comparative Example 1, within the range provided by the present disclosure, conditions of the mixing of the first ligand and the first inorganic nanoparticle have a certain influence on the luminous efficiency and the turn-on voltage of the photoelectric device, and the mixing temperature has a greater influence on the performance of the photoelectric device and may affect a connection between the first ligand and the first inorganic nanoparticle, but overall, luminous efficiencies of photoelectric devices of Examples 8˜11 are significantly improved, and turn-on voltages are decreased.

According to Examples 1, 12, 13 and Comparative Example 1, a thickness of the electron transport layer including the first ligand does not significantly affect the performance of the photoelectric device, and the conduction band energy level of the whole electron transport layer can be stepped by a layer without the first ligand and another layer including the first ligand, so as to alleviate problems of low electron mobility and difficulty in electron injection, promote the electron injection, reduce the turn-on voltage, and improve the luminous efficiency of the photoelectric device.

The photoelectric device, and the preparation method thereof by embodiments of the present disclosure are described in detail above, and specific examples have been applied herein to illustrate principles and implement measures. The foregoing description of embodiments is provided merely to help understand a method and a core idea of the present disclosure. Those skilled in the art may change specific embodiments and scope of the present disclosure according to ideas of the present disclosure. In summary, contents of the specification should not be construed as limiting the present disclosure.

What is claimed is:

1. A photoelectric device comprising an anode, a photoelectric functional layer, a first electron functional layer, a second electron functional layer, and a cathode disposed sequentially in stack;
wherein a material of the first electron functional layer comprises a first inorganic nanoparticle and a first ligand, and a material of the second electron functional layer comprises a second inorganic nanoparticle.

2. The photoelectric device according to claim 1, wherein in the first electron functional layer, a molar ratio of the first inorganic nanoparticle to the first ligand is 1:(100˜300).

3. The photoelectric device according to claim 1, wherein a number of carbon atoms in a main chain of the first ligand ranges from 2 to 10; the first ligand comprises a coordination group, and the coordination group comprises one or more of an amine group, a carboxyl group, a thiol group, a hydroxyl group, a cyano group, a carbonyl group, an ester group, an amide group, and an ether group.

4. The photoelectric device according to claim 3, wherein the number of carbon atoms in the main chain of the first ligand ranges from 2 to 6;
the first ligand comprises one or more of ethanolamine, ethylenediamine, diethylenetriamine, triethylenetetramine, ethylene diamine tetraacetic acid, 3-mercaptopropionic acid, thiophenol, 2-(methylamino) ethanol, oxalic acid, malic acid, caffeic acid, benzyl mercaptan, 2-(BOC-amino) ethanethiol, allyldiglycol, ethyl cyanoacetate, and 4-cyanobenzoic acid.

5. The photoelectric device according to claim 1, wherein a material of the first inorganic nanoparticle and a material of the second inorganic nanoparticle each independently comprise a first doped-type metal oxide particle, a first undoped-type metal oxide particle, a group IIB-VIA semiconductor material, a group IIIA-VA semiconductor material, and a group IB-IIIA-VIA semiconductor material; the first undoped-type metal oxide particle comprises one or more of ZnO, TiO₂, SnO₂, ZrO₂, and Ta₂O₅; the first doped-type metal oxide particle comprises one or more of ZnO, TiO₂, SnO₂, ZrO₂, Ta₂O₅ and Al₂O₃, and a doping element of the first doped-type metal oxide particle comprises one or more of Al, Mg, Li, Mn, Y, La, Cu, Ni, Zr, Ce, In, and Ga; the group IIB-VIA semiconductor material comprises one or more of ZnS, ZnSe, and CdS; the group IIIA-VA semiconductor material comprises one or more of InP and GaP; the group IB-IIIA-VIA semiconductor material comprises one or more of CuInS and CuGaS.

6. The photoelectric device according to claim 1, wherein the material of the first inorganic nanoparticle and the material of the second inorganic nanoparticle are the same or different;
an average particle size of the first inorganic nanoparticle ranges from 3 nm to 20 nm;
an average particle size of the second inorganic nanoparticle ranges from 3 nm to 20 nm;
a thickness of the first electron functional layer ranges from 10 nm to 30 nm;
a thickness of the second electron functional layer ranges from 10 nm to 30 nm.

7. The photoelectric device according to claim 1, wherein the material of the second electron functional layer further comprises a second ligand comprising one or more of an acetate ligand, a nitrate ligand, an oxalate ligand, a chloride ligand, a bromide ligand, and a diethyl ligand;
the material of the first electron functional layer further comprises a third ligand comprising one or more of an acetate ligand, a nitrate ligand, an oxalate ligand, a chloride ligand, a bromide ligand, and a diethyl ligand.

8. The photoelectric device according to claim 1, wherein the anode and the cathode each independently comprise one or more of a metal, a carbon material, and a metal oxide; the metal comprises one or more of Al, Ag, Cu, Mo, Au, Ba, Ca, Yb and Mg; the carbon material comprises one or more of graphite, carbon nanotube, graphene, and carbon fiber; the metal oxide comprises one or more of ITO, FTO, ATO, AZO, GZO, IZO, MZO, MoO₃ and AMO.

9. The photoelectric device according to claim 1, wherein a material of the photoelectric functional layer comprises a light-emitting material, and the light-emitting material comprises an organic light-emitting material or a quantum dot light-emitting material; the organic light-emitting material is selected from one or more of 4,4′-bis(N-carbazole)-1,1′-biphenyl:tris[2-(p-tolyl)pyridinyl iridium (III)], 4,4′,4″-tris(carbazol-9-yl)triphenylamine:tris[2-(p-tolyl)pyridinyl iridium], diarylanthracene derivatives, stilbene aromatic derivatives, pyrene derivatives, fluorene derivatives, a TBPe fluorescent material, a TTPX fluorescent material, a TBRb fluorescent material, a DBP fluorescent material, a DBP fluorescent material, a DBP fluorescent material, a TTA material, a TADF material, a polymer comprising a B—N covalent, a HLCT material, and an Exciplex luminescent material;
the quantum dot light-emitting material is selected from one or more of a quantum dot with a single component, a quantum dot with a core-shell structure, and a perovskite-type semiconductor material; a material of the quantum dot with the single component, a core material of the quantum dot with the core-shell structure, and a shell material of the quantum dot with the core-shell structure are each independently selected from one or more of a group II-VI compound, a group IV-VI compound, a group III-V compound, a group I-III-VI compound; the quantum dot with a core-shell structure comprises one or more shell layers;
the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the group I-III-VI compound is selected from one or more of CuInS₂, CuInSe₂, and AgInS₂; the quantum dot with the core-shell structure is selected from one or more of CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS;
the perovskite-type semiconductor material is selected from a doped inorganic perovskite type semiconductor, a non-doped inorganic perovskite type semiconductor, or an organic-inorganic hybrid perovskite type semiconductor; the inorganic perovskite type semiconductor has a general structural formula of AMX₃, wherein A is Cs⁺, and M is a divalent metal cation selected from one or more of Ph²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion selected from one or more of CI, Br, and I; the organic-inorganic hybrid perovskite type semiconductor has a general structural formula of BMX₃, where B is a formamidyl, and M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion selected from one or more of Cl, Br, and I.

10. The photoelectric device according to claim 1, wherein the photoelectric device further comprises a hole functional layer disposed between the anode and the photoelectric functional layer; a material of the hole functional layer comprises one or more of 4,4′-N,N′-dicarbazolyl-biphenyl, N,N′-diphenyl-N,N′-bis(1-naphthyl)-1,1′-biphenyl-4,4′-diamine, N,N′-diphenyl-N,N′-bis(3-methylphenyl)-(1,1′-biphenyl)-4,4′-diamine, N,N′-bis(3-methylphenyl)-N,N′-bis(phenyl)-spiro, N,N′-bis(4-(N,N′-diphenyl-amino)phenyl)-N, N′-diphenylbenzidine, 4,4′,4′-tris(N-carbazolyl)-triphenylamine, 4,4′,4″-tris(carbazol-9-yl)-triphenylamine, trichloroisocyanuric acid, a terbium-doped phosphate-based green luminescent material, hexaazatriphenylenchexacabonitrile, 4,4′,4″-tris(N-3-methylphenyl-N-phenylamino)triphenylamine, poly(9,9-dioctylfluorene-co-N-(4-butylphenyl)diphenylamine), poly[(9,9′-dioctylfluorene-2,7-diyl)-co-(4,4′-(N-(4-sec-butylphenyl)diphenylamine)], poly(4-butylphenyl-diphenylamine)], poly[bis(4-phenyl) (4-butylphenyl)amine], polyaniline, polypyrrole, poly(phenylenevinylene), poly[2-methoxy-5-(2-ethylhexyloxy)-1,4-phenylenevinylene], poly[2-methoxy-5-(3′,7′-dimethyloctyloxy)-1,4-phenylene vinylidene], copper (II) phthalocyanine, aromatic tertiary amine, polynuclear aromatic tertiary amine, 4,4′-bis(p-carbazolyl)-1,1′-biphenyl, N,N,N′,N′-tetraphenylbenzidine, PEDOT, PEDOT:PSS and derivatives thereof, PEDOT:PSS doped with s-MoO₃, poly(N-vinylcarbazole) and derivatives thereof, polymethacrylate and derivatives thereof, poly(9,9-octylfluorene) and derivatives thereof, poly(spirofluorene) and derivatives thereof, N,N′-bis(naphthalen-1-yl)-N,N′-diphenylbenzidine, spiro-NPB, nano-polycrystalline diamond, microcrystalline cellulose, tetracyanoquinone dimethane, doped graphene, undoped graphene, a second doped-type metal oxide particle, a second undoped-type metal oxide particle, a metal sulfide, a metal selenide and a metal nitride;
a metal oxide of the second doped-type metal oxide particle and the second undoped-type metal oxide particle each independently comprise one or more of MoO₃, WO₃, NiO, CrO₃, CuO, and V₂O₅; a doping element in the second doped-type metal oxide particle comprises Mo, W, Ni, Cr, Cu, and V; the metal sulfide comprises one or more of CuS, MoS₃, and WS₃; the metal selenide comprises one or more of MoSe₃ and WSe₃; the metal nitride comprises p-type gallium nitride.

11. A method for preparing a photoelectric device comprising:
providing a preform comprising an anode and a photoelectric functional layer disposed sequentially in stack;
disposing a first inorganic nanoparticle and a first ligand on the photoelectric functional layer to form a first electron functional layer;
disposing a second inorganic nanoparticle on the first electron functional layer to form a second electron functional layer; and
forming a cathode on the second electron functional layer to obtain the photoelectric device.

12. The method according to claim 11, wherein a number of carbon atoms in a main chain of the first ligand ranges from 2 to 10; the first ligand comprises a coordination group, and the coordination group comprises one or more of an amine group, a carboxyl group, a thiol group, a hydroxyl group, a cyano group, a carbonyl group, an ester group, an amide group, and an ether group.

13. The method according to claim 11, wherein the first ligand comprises one or more of ethanolamine, ethylenediamine, diethylenetriamine, triethylenetetramine, ethylene diamine tetraacetic acid, 3-mercaptopropionic acid, thiophenol, 2-(methylamino) ethanol, oxalic acid, malic acid, caffeic acid, benzyl mercaptan, 2-(BOC-amino) ethanethiol, allyldiglycol, ethyl cyanoacetate, and 4-cyanobenzoic acid;
a material of the first inorganic nanoparticle and a material of the second inorganic nanoparticle each independently comprise a first doped-type metal oxide particle, a first undoped-type metal oxide particle, a group IIB-VIA semiconductor material, a group IIIA-VA semiconductor material, and a group IB-IIIA-VIA semiconductor material; the first undoped-type metal oxide particle comprises one or more of ZnO, TiO₂, SnO₂, ZrO₂, and Ta₂O₅; the first doped-type metal oxide particle comprises one or more of ZnO, TiO₂, SnO₂, ZrO₂, Ta₂O₅ and Al₂O₃, and a doping element of the first doped-type metal oxide particle comprises one or more of Al, Mg, Li, Mn, Y, La, Cu, Ni, Zr, Ce, In, and Ga; the group IIB-VIA semiconductor material comprises one or more of ZnS, ZnSe, and CdS; the group IIIA-VA semiconductor material comprises one or more of InP and GaP; the group IB-IIIA-VIA semiconductor material comprises one or more of CuInS and CuGaS.

14. The method according to claim 11, wherein a step of forming the first electron functional layer comprises disposing the mixed solution comprising the first inorganic nanoparticle and the first ligand on the photoelectric functional layer to form the first electron functional layer.

15. The method according to claim 14, wherein in the mixed solution, a molar ratio of the first inorganic nanoparticle to the first ligand is 1:(100˜300);
the mixed solution comprises the first ligand and a first inorganic nanoparticle dispersion with the first inorganic nanoparticle, and in the first inorganic nanoparticle dispersion, a mass concentration of the first inorganic nanoparticle ranges from 15 mg/mL to 30 mg/mL;
the first inorganic nanoparticle dispersion further comprises a first solvent comprising one or more of chlorobenzene, diethylene glycol monobutyl ether, 3-methoxy-1-butanol, triethylene glycol monobutyl ether, diglyme, methanol, ethanol, 1-propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid, and cresol.

16. The method according to claim 14, wherein performing a first thermal annealing at a temperature ranging from 80° C. to 100° C. for 20 minutes˜30 minutes after disposing the mixed solution on the photoelectric functional layer.

17. The method according to claim 11, wherein a step of forming the second electron functional layer comprises disposing a second inorganic nanoparticle dispersion on the first electron functional layer to form the second electron functional layer.

18. The method according to claim 17, wherein in the second inorganic nanoparticle dispersion, a mass concentration of the second inorganic nanoparticle ranges from 15 mg/mL to 30 mg/mL, and the second inorganic nanoparticle dispersion further comprises a second solvent comprising one or more of chlorobenzene, diethylene glycol monobutyl ether, 3-methoxy-1-butanol, triethylene glycol monobutyl ether, diglyme, methanol, ethanol, 1-propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid, and cresol.

19. The method according to claim 17, wherein performing a second thermal annealing at a temperature ranging from 80° C. to 100° C. for 20 minutes˜30 minutes after disposing the second inorganic nanoparticle dispersion on the first electron functional layer.

20. A method for a photoelectric device comprising:
providing a preform comprising a cathode;
disposing a second inorganic nanoparticle on the cathode to form a second electron functional layer;
disposing a first inorganic nanoparticle and a first ligand on the second electron functional layer to form a first electron functional layer; and
forming a photoelectric functional layer and an anode sequentially on the first electron functional layer to obtain the photoelectric device.
